(19) United States
(12) Patent Application Publication
(10) Pub. No.: US 2014/0129885 A1
(43) Pub. Date: May 8, 2014

(54) SCAN CLOCK GENERATOR AND RELATED METHOD THEREOF

(71) Applicant: Realtek Semiconductor Corp., HsinChu (TW)

(72) Inventors: Ying-Yen Chen, Chiayi County (TW); Chen-Tung Lin, Taipei City (TW); Jih-Nung Lee, Hsinchu County (TW)

(73) Assignee: Realtek Semiconductor Corp., HsinChu (TW)

(21) Appl. No.: 14/051,428

(22) Filed: Oct. 10, 2013

(30) Foreign Application Priority Data
Nov. 5, 2012 (TW) 101140973

(51) Int. Cl. G01R 31/3185

(52) U.S. Cl. CPC G01R 31/318536
USPC 714/726

(57) ABSTRACT

An exemplary scan clock generator for providing a plurality of on-chip scan clocks to a plurality of cells under test includes: a receiving circuit, arranged for receiving an off-chip scan clock; and a clock processing circuit, coupled to the receiving circuit and arranged for generating the on-chip scan clocks according to the received off-chip scan clock; wherein clock edges of the on-chip scan clocks are staggered from each other, and the scan clock generator and the cells under test are set in a same chip.

### BACKGROUND OF THE INVENTION

1. Field of the Invention

The disclosed embodiments of the present invention relate to scan clock generation, and more particularly, to a scan clock generator for providing a plurality of scan clocks and related methods.

2. Description of the Prior Art

The scan test has an excellent ability for process defect detection, and can provide an accurate and a single estimation for testability and coverage regardless of the circuit size or function. Hence, scan test has become an important indicator for mass production of chips. However, in order to shorten the test time, the testing machine usually toggles the circuit as many times as possible while processing the scan test, to expect that a largest part of the circuit can be detected within a minimum time. Therefore, the test power consumption is often much larger than the circuit power consumption under normal operation. In a worst case, the excessive current may even damage chips under test or induce the result of over-kill. In order to avoid this drawback, the circuit is conventionally divided into several smaller blocks, each having its own independent scan clock. Besides, scan clocks of the blocks do not toggle at the same time during the test, and there is a phase skew between any two of the scan clocks. In other words, clock edges of the scan clocks are staggered from each other while the circuit is being tested. This approach effectively reduces the test power consumption. However, the circuit size continuous grows along with the increasing circuit complexity. Hence, a circuit under test needs to be fine-cut into more small blocks, which means that more scan clocks provided by the testing machine are needed to be inputted from the chip scan clock input ports to the internal circuit. However, the pin number of a chip package and the number of signals a testing machine can provide are fixed and limited. As a result, the growing number of scan clocks will finally exceed the number of pins (or test signals) that can be utilized.

Considering the above requirements, there is a need for an innovative design to be able to use a simple on-chip circuit to effectively reduce the number of pins (or testing signals) for scan test.

### SUMMARY OF THE INVENTION

Therefore, one of the objectives of the present invention is to provide a scan clock generator for providing a plurality of scan clocks and related methods to solve the above problems.

According to a first aspect of the present invention, a scan clock generator for providing a plurality of on-chip scan clocks to a plurality of cells under test is disclosed. The scan clock generator includes a receiving circuit and a clock processing circuit. The receiving circuit is arranged for receiving an off-chip scan clock. The clock processing circuit is coupled to the receiving circuit and arranged for generating the on-chip scan clocks according to the received off-chip scan clock. Wherein clock edges of the on-chip scan clocks are staggered, and the scan clock generator and the cells under test are set in a single chip.

According to a second aspect of the present invention, a scan clock generation method for providing a plurality of on-chip scan clocks to a plurality of cells under test is disclosed. The scan clock generation method includes: receiving an off-chip scan clock; and generating the on-chip scan clocks according to the received off-chip scan clock; wherein clock edges of the on-chip scan clocks are staggered.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a scan clock generator according to a first exemplary embodiment of the present invention.

FIG. 2 is a diagram illustrating the scan clock generator according to a second exemplary embodiment of the present invention.

FIG. 3 is a diagram illustrating the scan clock generator according to a third exemplary embodiment of the present invention.

FIG. 4 is a diagram illustrating the clock switching circuit shown in FIG. 3 according to an embodiment of the present invention.

FIG. 5 is a circuit diagram illustrating the controller shown in FIG. 4 according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

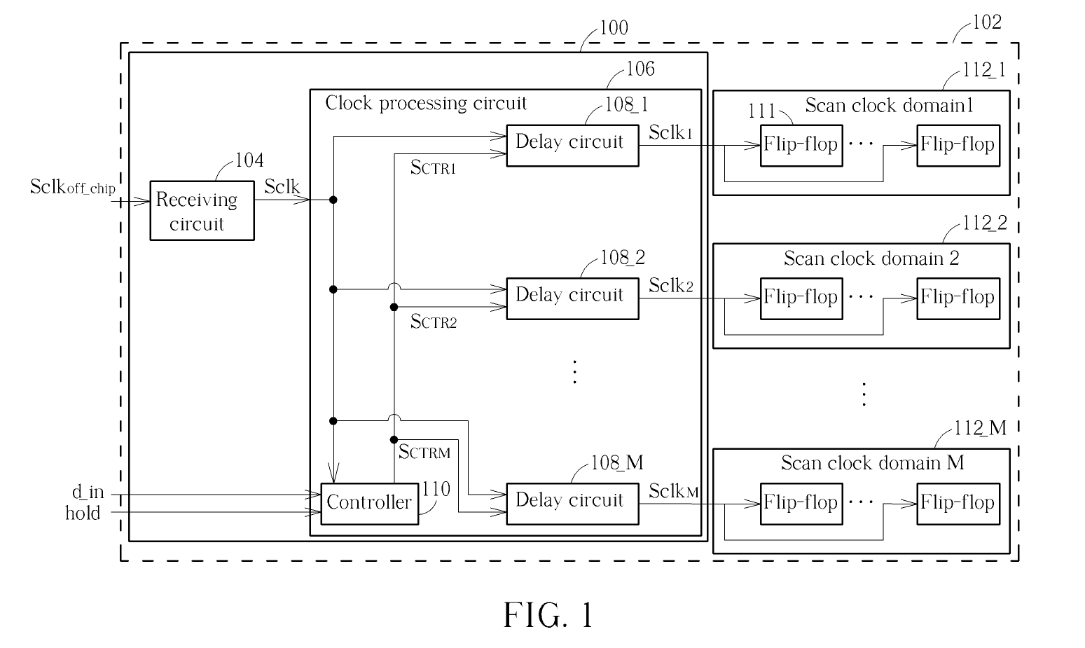

Please refer to FIG. 1, which is a diagram illustrating a scan clock generator according to a first exemplary embodiment of the present invention. In this exemplary embodiment, a scan clock generator 100 includes a receiving circuit 104 and a clock processing circuit 106 coupled to the receiving circuit 104, wherein the receiving circuit 104 is used to receive an off-chip scan clock sclk_{off}_{_{—}}_{chip} and output a scan clock sclk to the clock processing circuit 106. For instance, one or more buffers/inverters are set in the receiving circuit 104. In this embodiment, the clock processing circuit 106 may generate a plurality of on-chip scan clocks sclk₁, sclk₂, . . . , sclk_{M} based on the scan clock sclk. In addition, the clock edges of the on-chip scan clocks sclk₁, sclk₂, . . . , sclk_{M} are preferably staggered from each other, and are utilized as the scan test clock of the following scan clock domains 112_1, 112_2, . . . , 112_M. In other words, the on-chip scan clocks sclk₁, sclk₂, . . . , sclk_{M} are used to drive a plurality of cells under test in a plurality of scan clock domains under the scan test mode. For example (but not for limiting the scope of the present invention), the cells under test may include a plurality of flip-flops 111. In addition, the scan clock generator 100 and the scan clock domains are all configured in the same chip 102, and more specifically, the scan clock generator 100 and the cells under test are set in the same chip 102.

Regarding the clock processing circuit 106, it includes a controller 110 and a plurality of delay circuits 108_1, 108_2, . . . , 108_M, wherein the controller 110 is used to refer to the scan clock sclk, a control data serial input d_in and an input control signal hold to generate M delay control signals S_{CTR1}, S_{CTR2}, . . . , S_{CTRM}, which are inputted into a plurality of delay circuits 108_1, 108_2, . . . , 108_M, respectively. In this way, the delay circuits 108_1, 108_2, . . . , 108_M may impose corresponding delay time on the scan clock sclk in accordance with the delay control signals S_{CTR1}, S_{CTR2}, . . . , S_{CTRM} respectively, and obtain the desired relative relationship between phases of the scan clocks of the following scan clock domains. In other words, the delay circuits 108_1, 108_2, . . . , 108_M delay the received off-chip scan clock (i.e., sclk) individually in a parallel processing manner to generate the desired on-chip scan clocks respectively.

It should be noted that, in this exemplary embodiment, to reach the purpose of saving the input and output ports (I/O ports) of the chip 102, the control data serial input d_in of the controller 110 is inputted in a serial manner with the input control signal hold and the scan clock sclk serving as a basis on which the controller 110 can depend to identify the control data serial input d_in. More particularly, users can set the delay time/delay amount of the delay circuits 108_1, 108_2, . . . , 108_M arbitrarily through the control data serial input d_in located outside the chip. The input method of the controller 110, however, only serves as an example, and is not a limitation of the present invention. Any alternative designs which are able to achieve similar functions all belong to the scope of the present invention.

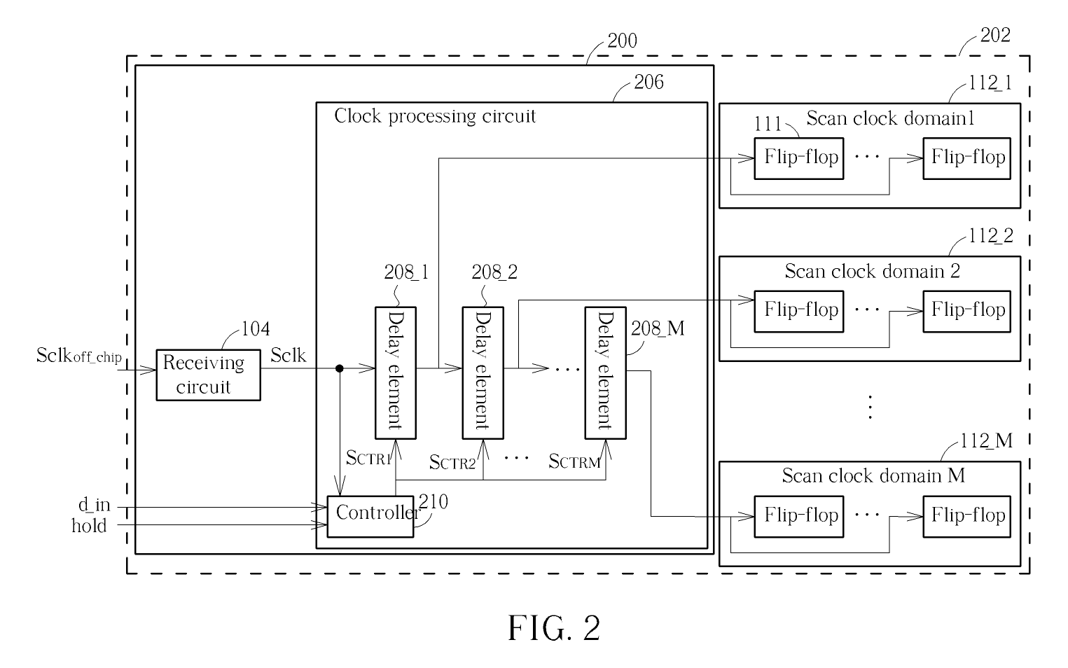

Please refer to FIG. 2, which is a diagram illustrating the scan clock generator according to a second exemplary embodiment of the present invention. In this exemplary embodiment, the scan clock generator 200 includes the aforementioned receiver 104 and a clock processing circuit 206, wherein the receiving circuit 104 is used to receive an off-chip scan clock sclk_{off}_{_{—}}_{chip} and output scan clock sclk to the clock processing circuit 206, so that the clock processing circuit 206 can generate a plurality of on-chip scan clocks sclk₁, sclk₂, . . . , sclk_{M} based on the scan clock sclk. Regarding the operational principle and concept between the on-chip scan clocks sclk₁, sclk₂, . . . , sclk_{M} and the subsequent scan clock domains 112_1, 112_2, . . . , 112_M are substantially the same as foregoing exemplary embodiment. Thus, the detailed description is omitted here for brevity. It should be noted that the scan clock generator 200 and the scan clock domains 112_1, 112_2, . . . , 112_M are all located at the same chip 202, and more particularly, the scan clock generator 200 and the cells under test are disposed on the same chip.

Regarding the clock processing circuit 206, it includes a controller 210 and a plurality of delay elements 208_1, 208_2, . . . , 208_M, wherein the controller 210 is used to refer to the scan clock sclk, a control data serial input d_in and an input control signal hold to generate M delay control signals S_{CTR1}, S_{CTR2}, . . . , S_{CTRM}, which are inputted into a plurality of delay circuits 208_1, 208_2, . . . , 208_M, respectively. It should be noted that, in this exemplary embodiment, the delay elements 208_1, 208_2, . . . , 208_M are serially connected. That is, the output terminal of the delay element 208_1 is coupled to the input terminal of the following delay element 208_2, and the output terminal of the delay element 208_2 is coupled to the input terminal of the following delay element 208_3. As to the subsequent delay elements, they are connected in the same manner. Therefore, the delay elements 208_1, 208_2, . . . , 208_M may impose the corresponding delay time on the scan clock sclk in accordance with the delay control signals S_{CTR1}, S_{CTR2}, . . . , S_{CTRM} respectively. For instance, in a case where sclk is taken as a reference clock, the delay time of the scan clock sclk₁, when compared to sclk, is the delay time provided by the delay element 208_1, the delay time of the scan clock sclk₂, when compared to sclk, is the total delay time provided by the delay element 208_1 and the delay element 208_2, and so forth. Therefore, the delay time of the last scan clock sclk_{M}, when compared to sclk, is the total delay time provided by the delay elements 208_1, 208_2, . . . , 208_M. In other words, the delay elements 208_1, 208_2, . . . , 208_M are serially connected to sequentially delay the received off-chip scan clock (i.e., sclk), and thereby generate the desired on-chip scan clocks. In addition, the operation flow of the controller 210 is the same as the foregoing exemplary embodiment, and thus the detailed description is omitted here for brevity.

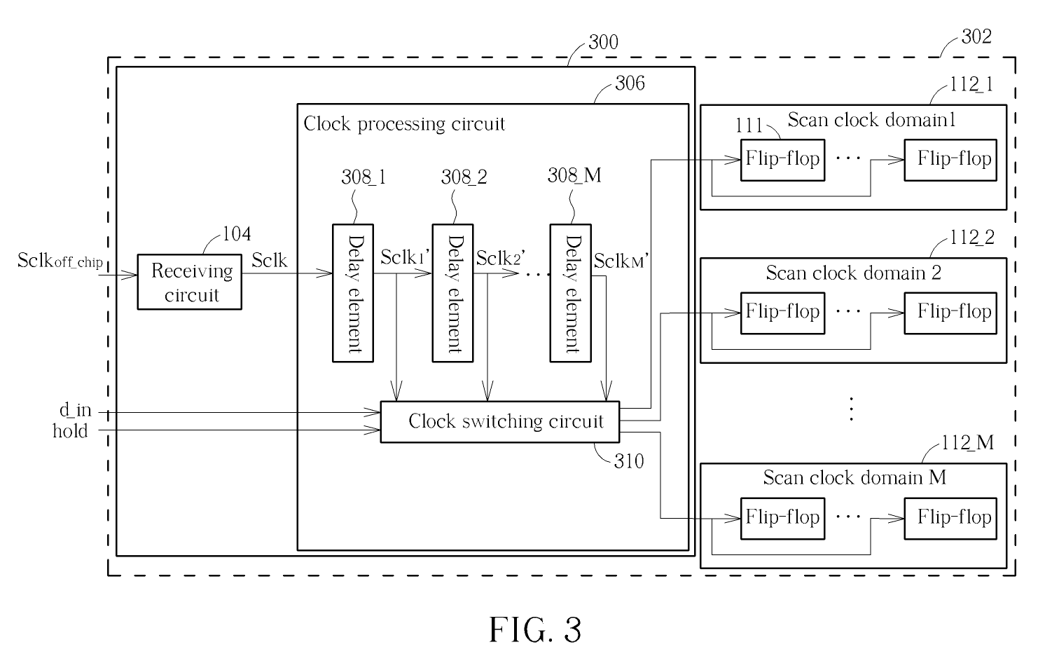

Please refer to FIG. 3, which is a diagram illustrating the scan clock generator according to a third exemplary embodiment of the present invention. In this exemplary embodiment, the scan clock generator 300 includes the aforementioned receiver 104 and a clock processing circuit 306, wherein the receiving circuit 104 is used to receive an off-chip scan clock sclk_{off}_{_{—}}_{chip} and output scan clock sclk to the clock processing circuit 306, so that the clock processing circuit 306 can generate a plurality of on-chip scan clocks sclk₁, sclk₂, . . . , sclk_{M} based on the scan clock sclk. Regarding the operational principle and concept between the on-chip scan clocks sclk₁, sclk₂, . . . , sclk_{M} and the subsequent scan clock domains 112_1, 112_2, . . . , 112_M, they are substantially the same as foregoing exemplary embodiment. Thus, the detailed description is omitted here for brevity. It should be noted that the scan clock generator 300 and the scan clock domains 112_1, 112_2, . . . , 112_M are provided on the same chip 202, and more particularly, the scan clock generator 300 and the cells under test are disposed on the same chip.

Regarding the clock processing circuit 306, it includes a clock switching circuit 310 and a plurality of delay elements 308_1, 308_2, . . . , 308_M, wherein the scan clocks sclk₁′, sclk₂′ . . . , sclk_{M}′ outputted by the delay elements 308_1, 308_2, . . . , 308_M are inputted into the clock switching circuit 310. It should be noted that, in this exemplary embodiment, the delay elements 308_1, 308_2, . . . , 308_M are serially connected. That is, the output terminal of the delay element 308_1 is coupled to the input terminal of the following delay element 308_2, and the output terminal of the delay element 308_2 is coupled to the input terminal of the following delay element 308_3. As to the subsequent delay elements, they are connected in the same manner. In addition, the clock switching circuit 310 will refer to the scan clock sclk, a control data serial input d_in and an input control signal hold to correspondingly reorder the scan clocks sclk₁′, sclk₂′ , . . . , sclk_{M}′ generated by the delay elements 308_1, 308_2, . . . , 308_M, and further output the scan clock sclk₁′, sclk₂′, . . . , sclk_{M}′ in a new order as the on-chip scan clocks sclk₁, sclk₂, . . . , sclk_{M}. Therefore, the scan clock settings of the following scan clock domains 112_1, 112_2, . . . , 112_M can be modified via the scan clock sclk, the control data serial input d_in, and the input control signal hold. To put it another way, users can reconfigure the relationship of phases between the scan clocks of the cells under test by external control.

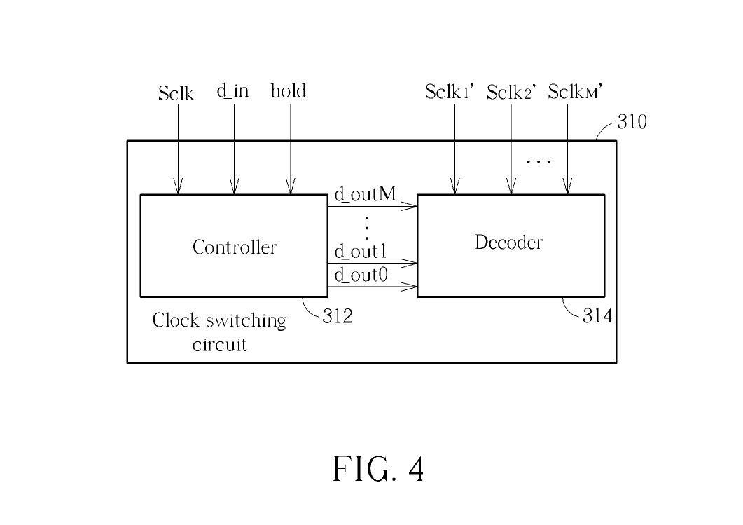

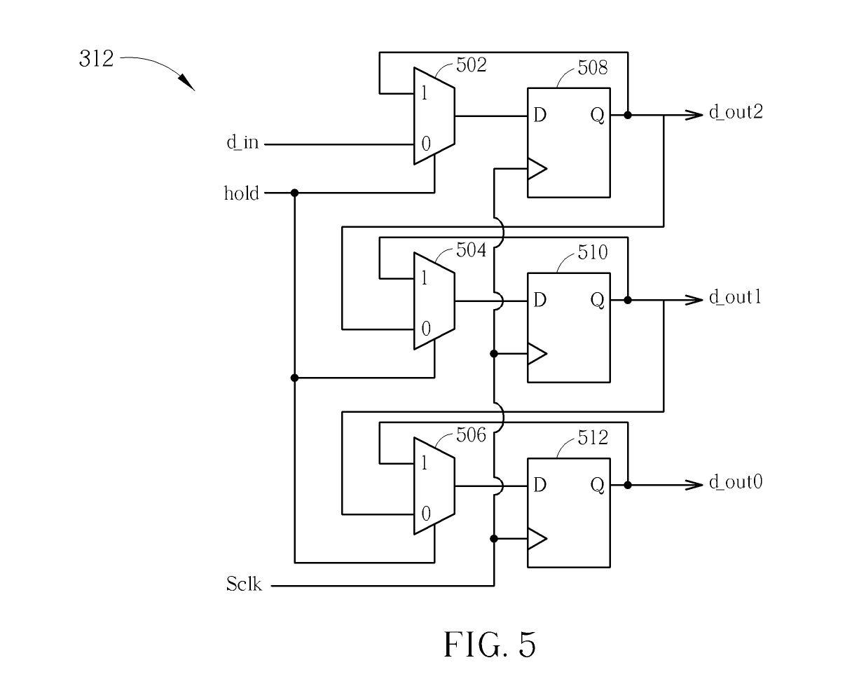

FIG. 4 is a diagram illustrating the clock switching circuit 310 shown in FIG. 3 according to an embodiment of the present invention. The clock switching circuit 310 includes a controller 312 and a decoder 314, wherein the controller 312 refers to the scan clock sclk and the input control signal hold to read the externally inputted control data serial input d_in, and converts it to a control data parallel output d_out0, d_out1, . . . , d_outM, where the control data parallel output d_out0, d_out1, . . . , d_outM is transmitted to the decoder 314 to serve as a basis for changing the order of sclk₁′, sclk₂′, . . . , sclk_{M}′ to the order of sclk₁, sclk₂, . . . , sclk_{M}. Please refer to FIG. 5, which is a circuit diagram illustrating the controller 312 shown in FIG. 4 according to an embodiment of the present invention. The controller 312 includes a plurality of multiplexers 502, 504, and 506 for switching between inputs according to the input control signal hold, and a plurality of flip-flops 508, 510, and 512 (e.g., D-type flip-flops) driven by the scan clock sclk. When the first bit of the control signal hold changes from ‘1’ to ‘0’, a first bit of the control data serial input d_in would be inputted to the flip-flop 508 and be stored therein, and at the next clock cycle, the first bit would be inputted to the flip-flop 510 and be stored therein, and a second bit of the control data serial input d_in would be inputted to the flip-flop 508 and be stored therein, and so on. Therefore, at yet next clock cycle, the first bit of the control data serial input d_in would be stored in the flip-flop 512, the second bit of the control data serial input d_in would be stored in the flip-flop 510, and a third bit of the control data serial input d_in would be stored in the flip-flop 508. In addition, the control signal hold would change from 0 to 1 at this moment to make the data remained in the flip-flops 508-512, until next time a new control data serial input d_in needs to be written. The architecture as well as the number of bits of the controller 312 only serve as an example in this description, not the limitations of the present invention. In practice, the number of bits may depend on the number of scan clock domains, and any architecture design which can achieve similar functionality belongs to the scope of the present invention.

In summary, the proposed scan clock generator and scan clock generation method can use an off-chip/external scan clock outside a chip to provide a plurality of on-chip scan clock with a plurality of different phases, thereby reducing the need of multiple scan clock input pins in a scan test mode. At the same time, as the scan clock generator of the present invention can generate multiple on-chip/internal scan clocks with different phases can also achieve the objective of lowering the instant test power.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A scan clock generator for providing a plurality of on-chip scan clocks to a plurality of cells under test, comprising:
a receiving circuit, for receiving an off-chip scan clock; and
a clock processing circuit, coupled to the receiving circuit and arranged for generating the on-chip scan clocks according to the received off-chip scan clock;
wherein clock edges of the on-chip scan clocks are staggered from each other, and the scan clock generator and the cells under test are set in a same chip.

2. The scan clock generator of claim 1, wherein the clock processing circuit comprises:
a plurality of delay circuits, arranged for delaying the received off-chip scan clock respectively to generate the plurality of on-chip scan clocks.

3. The scan clock generator of claim 2, wherein the clock processing circuit comprises:
a controller, coupled to the plurality of delay circuits and arranged for adjusting a delay time of each delay circuit.

4. The scan clock generator of claim 1, wherein the clock processing circuit comprises:
a delay circuit, arranged for delaying the received off-chip scan clock to generate the plurality of on-chip scan clocks respectively, wherein the delay circuit comprises a plurality of serially connected delay elements.

5. The scan clock generator of claim 4, wherein the clock processing circuit further comprises:
a controller, coupled to the plurality of delay elements and arranged for adjusting a delay time of each delay element.

6. The scan clock generator of claim 4, wherein the clock processing circuit further comprises:
a clock switching circuit, arranged for switching interconnections between the plurality of on-chip scan clocks and the plurality of cells under test.

7. The scan clock generator of claim 6, wherein the clock switching circuit comprises:
a controller, arranged for generating a control signal; and
a decoder, coupled to the controller and the plurality of serially connected delay elements, the decoder arranged for decoding the control signal to adjust the interconnections between the plurality of on-chip scan clocks and the plurality of cells under test.

8. The scan clock generator of claim 7, wherein the controller receives a plurality of control bits, and generates the control signal based on the plurality of control bits; and the plurality of control bits are inputted to the controller based on serial transmission.

9. A scan clock generation method for providing a plurality of on-chip scan clocks to a plurality of cells under test, comprising:
receiving an off-chip scan clock; and
generating the on-chip scan clocks according to the received off-chip scan clock;
wherein clock edges of the on-chip scan clocks are staggered from each other.

10. The scan clock generation method of claim 9, wherein the step of generating the on-chip scan clocks according to the received off-chip scan clock comprises:
delaying the received off-chip scan clock individually in a parallel processing manner to generate the plurality of on-chip scan clocks respectively.

11. The scan clock generation method of claim 9, wherein the step of generating the on-chip scan clocks according to the received off-chip scan clock comprises:
delaying the received off-chip scan clock sequentially by way of serial connection to generate the plurality of on-chip scan clocks respectively.

12. The scan clock generation method of claim 11, wherein the step of generating the on-chip scan clocks according to the received off-chip scan clock further comprises:
switching interconnections between the plurality of on-chip scan clocks and the plurality of cells under test.

13. The scan clock generator of claim 12, wherein the step of switching the interconnections between the plurality of on-chip scan clocks and the plurality of cells under test comprises:
generating a control signal; and
decoding the control signal to adjust the interconnections between the plurality of on-chip scan clocks and the plurality of cells under test.

14. The scan clock generator of claim 13, wherein the step of generating the control signal comprises:
receiving a plurality of control bits via serial transmission; and
generating the control signal based on the plurality of control bits.
